(19) United States
(12) Patent Application Publication
(10) Pub. No.: US 2012/0080748 A1
(43) Pub. Date: Apr. 5, 2012

(54) TRENCH MOSFET WITH SUPER PINCH-OFF REGIONS

(75) Inventor: Fu-Yuan HSIEH, Banciao City (TW)

(73) Assignee: FORCE MOS TECHNOLOGY CO., LTD., Banciao City (TW)

(21) Appl. No.: 12/894,653

(22) Filed: Sep. 30, 2010

(51) Int. Cl. H01L 29/78; H01L 21/336

(52) U.S. Cl. 257/331; 438/270; 257/E21.409; 257/E29.255

(57) ABSTRACT

A trench MOSFET with short channel length and super pinch-off regions is disclosed, wherein the super pinch-off regions are implemented by forming at least two type pinch-off regions for punch-through prevention: a first type pinch-off region with a wide mesa width generated between lower portion of two adjacent trenched gates and below an anti-punch through region surrounding bottom of a trenched source-body contact filled with metal plug; a second type pinch-off region with a narrow mesa width generated below a body region and between upper portion of one trenched gate and the anti-punch-through region along sidewall of the trenched source-body contact.

### FIELD OF THE INVENTION

This invention relates generally to the cell structure, device configuration and fabricating method of semiconductor devices. More particularly, this invention relates to an improved trench MOSFET (Metal Oxide Semiconductor Field Effect Transistor) configuration with short channel length having super pinch-off regions for Idsx (leakage current between drain and source) reduction.

### BACKGROUND OF THE INVENTION

Please refer to FIG. 1 for an N-channel trench MOSFET of prior art (U.S. Pat. No. 6,285,060) formed in an N− drift region 100 onto an N+ substrate 102. A plurality of trenched gates are filled with doped poly-silicon 103 padded by a gate oxide layer 104, wherein the portion of the gate oxide layer on bottom of the trenched gates is thicker than that along sidewall of the trenched gates for Qgd (charge between gate and drain) reduction. P body region 105 is shallow, defining a short channel length between N+ source region 106 and the N− drift region 100 adjacent the sidewall of the trenched gates. Source metal 107 is formed on top of the trench MOSFET, connecting the N+ source regions 106 and the P body regions 105 horizontally. The N-channel trench MOSFET of prior art in FIG. 1 has one electric field pinch-off region between two adjacent of the trenched gates, allowing short channel length formation without having severe punch-through problem, however, there are still some disadvantage constraining performance of the trench MOSFET. The prior art used a planar contact structure for source-body contact in a mesa between every two adjacent of the trenched gates, which occupies large contact area for contacting to both the N+ source region 106 and the P body region 105 horizontally, resulting in difficulty for the mesa width shrinkage. Furthermore, as less mesa width has less Idsx (the leakage current between drain and source), thus the Idsx can not be further reduced because pinch effect of the electric field in the mesa is so strongly related to the mesa width.

Moreover, Qgd (charge between gate and drain) is still high in the N-channel trench MOSFET in FIG. 1 because only the bottom of the trenched gate has thick gate oxide while a large amount trenched gate sidewall area having thin gate oxide along with results in high Qgd.

Accordingly, it would be desirable to provide a new and improved device configuration for better pinch effect and for lower Idsx and lower Qgd.

### SUMMARY OF THE INVENTION

It is therefore an object of the present invention to provide a new and improved semiconductor power device such as a trench MOSFET with trenched source-body contact structure and super pinch-off regions for better pinch-off performance. In an N-channel trench MOSFET, super pinch-off regions are implemented by forming two type pinch-off regions as shown in FIG. 2: wherein a first type pinch-off region R1 with a wide mesa width Wₘ₁<1.3 um is generated between the lower portion of two adjacent trenched gates and below an anti-PT (anti-Punch Through) P* region 210 surrounding the bottom of a trenched source-body contact filled with metal plug 207; a second type pinch-off region R2 with a narrow mesa width Wₘ₂<0.5 um is generated below a P body region 205 and between the upper portion of one trenched gate and the anti-PT P* region 210 along the sidewall of the trenched source-body contact filled with metal plug 207. Junction depth of the P body region 205 in an N− epitaxial layer 200 is shallower than that of the anti-PT P* region 210 in the portion below the bottom of the trenched source-body contact.

By employing the trench MOSFET according to the present invention, the device can be significantly shrunk with the trenched source-body contact instead of planar contact in prior art. Furthermore, the super pinch-off regions having two type pinch-off regions results in Idsx reduction as shown in FIG. 3, which shows the Idsx is dramatically decreased when the wide mesa width Wₘ₁<1.3 um and the narrow mesa width Wₘ₂<0.5 um. Besides, the two type pinch-off regions allow short channel length formation with channel length<0.3 um without having punch-through problem for Rds (resistance between drain and source) reduction.

Briefly, in a preferred embodiment, this invention discloses a trench MOSFET with super pinch-off regions comprising: a semiconductor chip comprising a substrate of a first conductivity doping type and an epitaxial layer of the first conductivity doping type, wherein the epitaxial layer formed onto the top surface of the substrate and having lower doping concentration than the substrate; a plurality of trenched gates extending from the top surface of the semiconductor chip and filled with a conductive material such as doped poly-silicon which insulated by a gate oxide layer from the semiconductor chip, wherein the doped poly-silicon can be n+ doped or p+ doped poly-silicon for threshold voltage adjustment; a source region of the first conductivity doping type located near the top surface of a mesa which is defined by an area between every two adjacent of the trenched gates; a body region of a second conductivity doping type located in the mesa below the source region and adjacent to the sidewall of the trenched gate; a contact interlayer formed onto the top surface of the semiconductor chip; a trenched source-body contact filled with metal plug penetrating through the contact interlayer, the source region and the body region, and extending into the epitaxial layer in the mesa, wherein the depth of the trenched source-body contact is shallower than bottom of the trenched gate; an anti-PT region of the second conductivity doping type wrapping around the sidewall and the bottom of the trenched source-body contact below the source region, wherein the anti-PT region having higher doping concentration than the body region, and junction depth of the body region in the epitaxial layer is shallower than that of the anti-PT region in the portion below the bottom of the trenched source-body contact.

In other preferred embodiments, this invention include one or more of following features: the wide mesa width between every two adjacent of the trenched gates is less than 1.3 um, and the narrow mesa width between the sidewall of the anti-PT region and adjacent trenched gate is less than 0.5 um; the contact interlayer comprising a BPSG (Boron Phosphorus Silicon Glass) layer and a NSG (None-doped Silicon Glass) layer beneath; the trenched source-body contact having greater trench width within the BPSG layer than within the NSG layer for contact resistance reduction between the metal plug filled in the trenched source-body contact and a source metal overlying the contact interlayer; the trenched source-body contact having vertical sidewall within the source region and the body region; the trenched source-body contact having tapered sidewall within the source region, the body region and the epitaxial layer; the trenched source-body contact having vertical sidewall within the source region while having tapered sidewall within the body region and the epitaxial layer; the gate oxide is single gate oxide; the gate oxide is double gate oxide for Qgd reduction, which having greater thickness along the bottom and the lower portion of the trenched gate sidewall than along the upper portion of the trenched gate sidewall; the portion of the gate oxide having greater thickness is encompassed in the epitaxial layer and not reaching the substrate; the portion of the gate oxide having greater thickness penetrates into the substrate; the metal plug is tungsten plug padded by a barrier layer of Ti/TiN or Co/TiN or Ta/TiN; the trench MOSFET further comprising a source metal padded by a resistance-reduction layer of Ti or TiN beneath which formed onto the contact interlayer and connecting to the metal plug filled in the trenched source-body contact; the trench MOSFET further comprising a single implanted pinch-off island of the second conductivity doping type in the epitaxial layer underneath the anti-PT region and between every two adjacent of the trenched gates to form a third type pinch-off region between the trenched gate sidewall and the single implanted pinch-off island for the Idsx reduction; the trench MOSFET further comprising multiple implanted pinch-off islands of the second conductivity doping type in the epitaxial layer underneath the anti-PT region and between every two adjacent of the trenched gates; the MOSFET further comprising a implanted pinch-off column region formed by multiple implanted pinch-off islands of the second conductivity doping type in the epitaxial layer underneath the anti-PT region and between every two adjacent of the trenched gates; the trench MOSFET further comprising a termination area comprising multiple floating trenched gates so that the shallow body can be used without degrading BV (breakdown voltage); wherein the first conductivity doping type is N type, and the second conductivity type is P type; wherein the first conductivity doping type is P type, and the second conductivity type is N type.

This invention further disclosed a method of manufacturing a trench MOSFET with super pinch-off regions comprising the steps of: opening a plurality of gate trenches in an epitaxial layer of a first conductivity type which supported onto a substrate of the first conductivity type; forming a gate oxide layer covering the inner surface of the gate trenches and the top surface of the epitaxial layer; depositing doped poly-silicon padded by the gate oxide layer and etching back to keep the doped poly-silicon within the gate trenches; carrying out ion implantation of a second conductivity doping type dopant for formation of body region; carrying out ion implantation of the first conductivity doping type dopant for formation of source region; depositing a layer of NSG and a layer of BPSG successively onto entire top surface; applying a contact mask and carrying out dry oxide etching and dry silicon etching successively to open a contact trench between two adjacent of the gate trenches through the BPSG layer, the NSG layer, the source region, the body region and into the epitaxial layer; carrying out zero degree and angle ion implantation of the second conductivity doping type dopant for formation of anti-PT region surrounding the bottom and the sidewall of the contact trench below the source region; carrying out zero degree ion implantation of the second conductivity doping type dopant for formation of implanted islands underneath the anti-PT region.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET of prior art.

FIG. 2 is a cross-sectional view of a preferred embodiment according to the present invention.

FIG. 3 is a profile showing relationship between mesa width and Idsx.

FIG. 4 is a cross-sectional view of another preferred embodiment according to the present invention.

FIG. 5A is a cross-sectional view of another preferred embodiment according to the present invention.

FIG. 5B is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 7A is a cross-sectional view of another preferred embodiment according to the present invention.

FIG. 7B is a cross-sectional view of another preferred embodiment according to the present invention.

FIG. 7C is a cross-sectional view of another preferred embodiment according to the present invention.

FIG. 8A is a cross-sectional view of another preferred embodiment according to the present invention.

FIG. 8B is a cross-sectional view of another preferred embodiment according to the present invention.

FIG. 8C is a cross-sectional view of another preferred embodiment according to the present invention.

FIGS. 9A-9E are a serial of side cross-sectional views for showing the processing steps for fabricating the trench MOSFET having super pinch-off regions as shown in FIG. 6B.

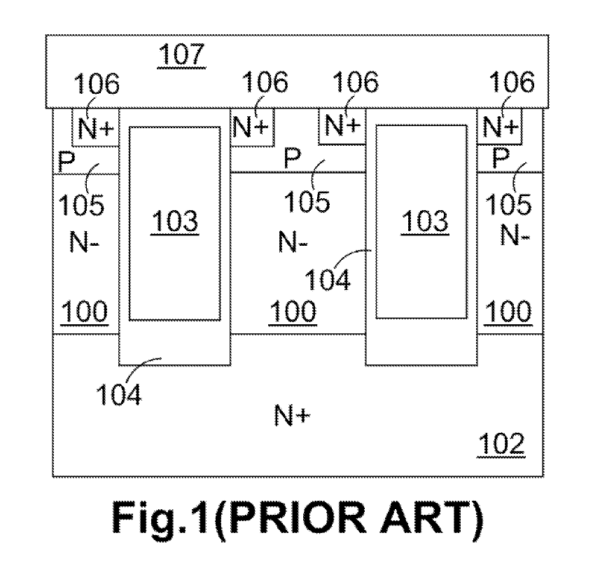

### DETAILED DESCRIPTION OF THE EMBODIMENTS

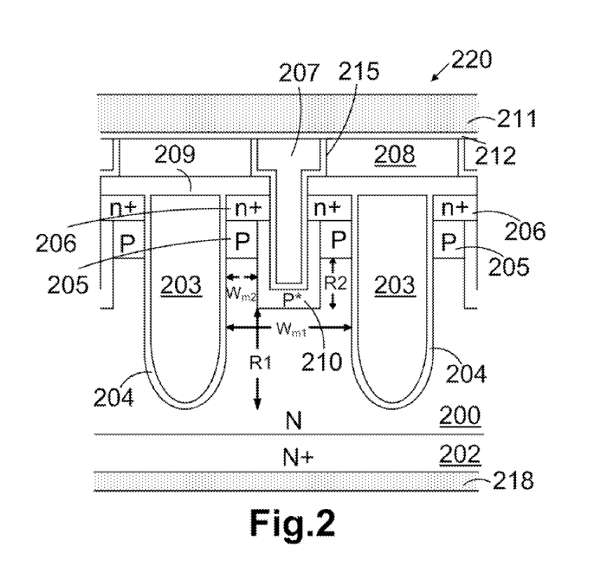

Please refer to FIG. 2 for a preferred N-channel trench MOSFET 220 with super pinch-off regions according to the present invention. The N-channel trench MOSFET 220 is formed in an N epitaxial layer 200 supported on a heavily doped N+ substrate 202 which coated with back metal 218 on the rear side as drain. A plurality of trenched gates are extending from the top surface of the N epitaxial 200, wherein each of the trenched gates filled with n+ or p+ doped poly-silicon 203 padded by a single gate oxide layer 204. In a wide mesa defined by an area between two adjacent of the trenched gates, a P body region 205 is formed below n+ source region 206 which near the top surface of the mesa. A trenched source-body contact 215 having vertical sidewall and filled with tungsten plug 207 padded by a barrier layer of Ti/TiN or Ta/TiN or Co/TiN is penetrating through a contact interlayer comprising a BPSG layer 208 and a NSG layer 209 beneath, further through the n+ region 206, the P body region 205 and extending into the N epitaxial layer 200, wherein the trenched source-body contact 215 having greater trench width in the BPSG layer 208 than in the NSG layer 209. An anti-PT P* region 210 is surrounding the bottom and the sidewall of the trenched source-body contact 215 below the n+ source region 206. According to this invention, the wide mesa width Wₘ₁ is less than 1.3 um and a narrow mesa width Wₘ₂ is less than 0.5 um, therefore, a first type pinch-off region R1 is generated by the lower portion of two adjacent of the trenched gates and below the P*/N-epitaxial junction on bottom of the trenched source-body contact 215, and a second type pinch-off region R2 is generated by the upper portion of one trenched gate and the P*/N-epitaxial junction along the sidewall of the trenched source-body contact 215 below the P-body/N-epitaxial junction. On the other hand, the anti-PT P* region 210 also acts as P body contact resistance reduction region for forming ohmic contact between the tungsten plug 207 and the P body region 205 with surface doping concentration of the anti-PT P* region 210 along the sidewall of the trenched source-body trenched contact 215 greater than 1E18 cm⁻³. The N-channel trench MOSFET 220 further comprises a source metal 219 padded by a resistance-reduction layer 212 of Ti or TiN onto the contact interlayer to contact with the tungsten plug 207. The source region in FIG. 2 has a doping concentration along a channel region same as that along the trenched source-body contact 215 at a same distance from the surface of the epitaxial layer, and the junction depth of the source region 206 along the channel region is same as along the trenched source-body contact 215.

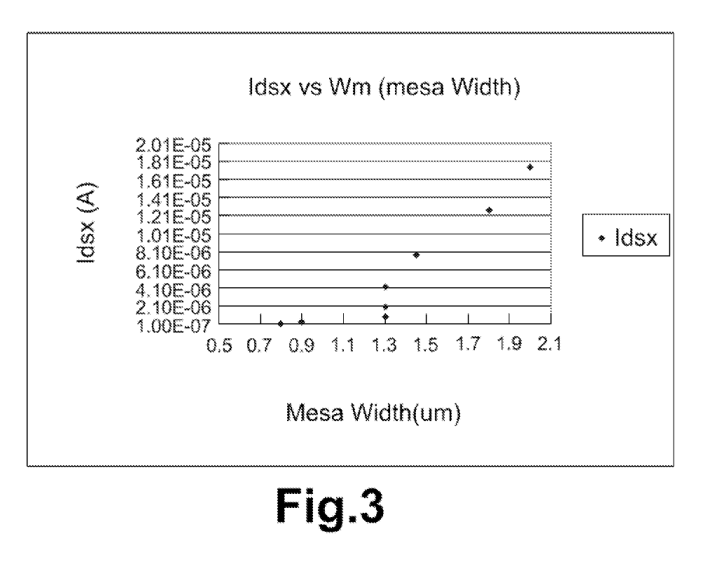

Please refer to FIG. 3 for relationship between the mesa width and Idsx, from which it can be seen that, Idsx is dramatically decreased when the wide mesa width Wₘ₁ less than 1.3 um and the narrow mesa width Wₘ₂ less than 0.5 um.

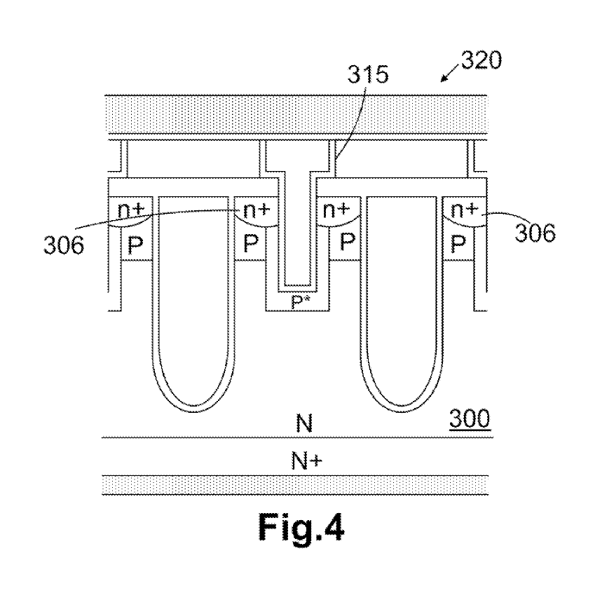

Please refer to FIG. 4 for another preferred N-channel trench MOSFET 320 with super pinch-off regions according to the present invention, which has similar configuration to FIG. 2 except that, the source region 306 has a doping concentration along a channel region lower than along the trenched source-body contact 315 at a same distance from the surface of the epitaxial layer 300, and the junction depth of the source region 306 along the channel region is shallower than that along the trenched source-body contact 315, and the doping profile of the source region 306 along the surface of the epitaxial layer 300 has a Gaussian-distribution from the trenched source-body contact 315 to the channel region.

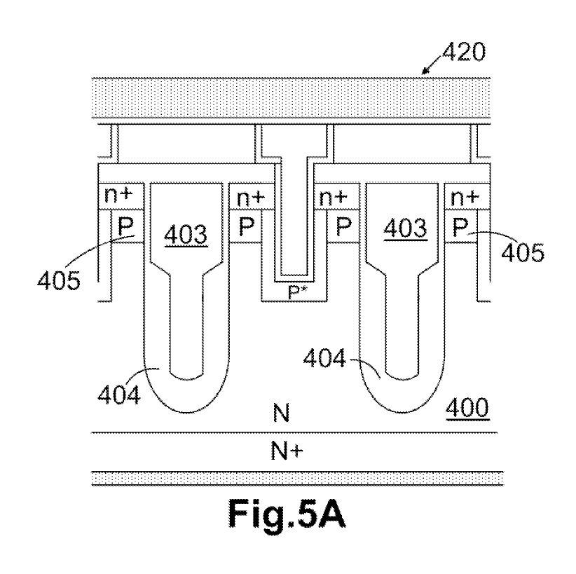

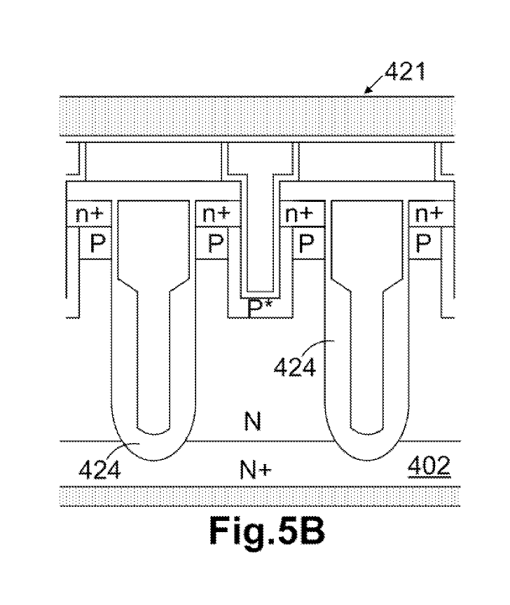

Please refer to FIG. 5A for another preferred N-channel trench MOSFET 420 with super pinch-off regions according to the present invention, which has similar configuration to FIG. 2 except that, the gate oxide 404 in FIG. 4A has double gate oxide for Qgd reduction, which has greater thickness along the bottom and the lower portion of the trenched gate sidewall than along the upper portion of the trenched gate sidewall. Therefore, each of doped poly-silicon 403 filled into the trenched gate includes an upper gate portion and a lower gate portion wherein the lower gate portion is surrounded with the lower gate oxide layer having a greater thickness than the upper gate oxide layer surrounding the upper gate portion; and the P body region 405 disposed above the lower gate portion of the trenched gate.

Please refer to FIG. 5B for another preferred N-channel trench MOSFET 421 with super pinch-off regions according to the present invention, which has similar configuration to FIG. 5A except that, the bottom of gate oxide 424 having greater thickness penetrates into N+ substrate 402 instead of totally encompassed in N epitaxial layer 400 in FIG. 4A for further Rds reduction.

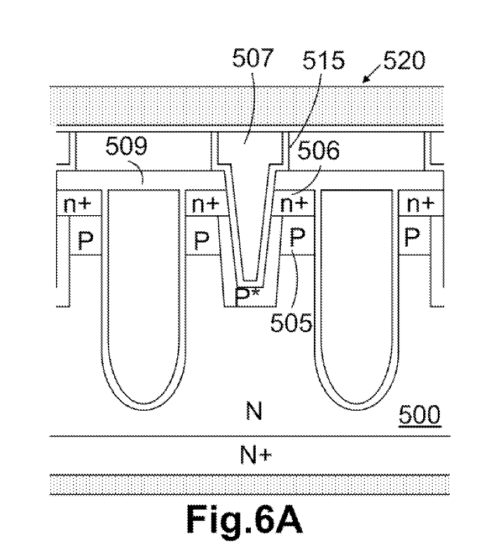

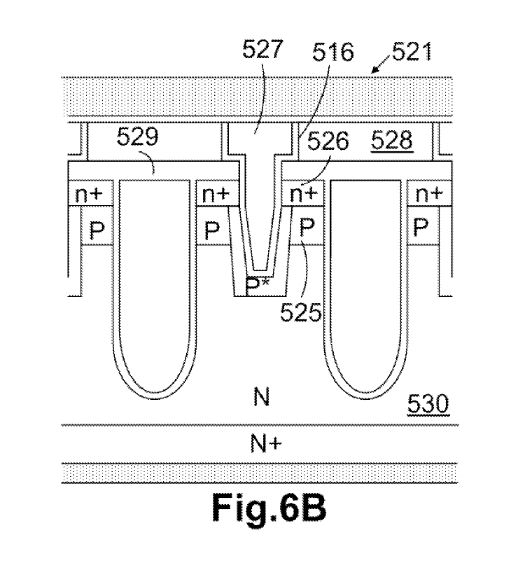

Please refer to FIG. 6A for another preferred N-channel trench MOSFET 520 with super pinch-off regions according to the present invention, which has similar configuration to FIG. 2 except that, trenched source-body contact 515 filled with tungsten plug 507 has slope sidewall in NSG layer 509, in n+ source region 506, in P body region 505 and in N epitaxial layer 500 for better source-body contact performance.

Please refer to FIG. 6B for another preferred N-channel trench MOSFET 521 with super pinch-off regions according to the present invention, which has similar configuration to FIG. 2 except that, trenched source-body contact 516 filled with tungsten plug 527 has vertical sidewall in BPSG layer 528, in NSG layer 529 and in n+ source region 526, while having slope sidewall in P body region 525 and in N epitaxial layer 530 for Rds reduction.

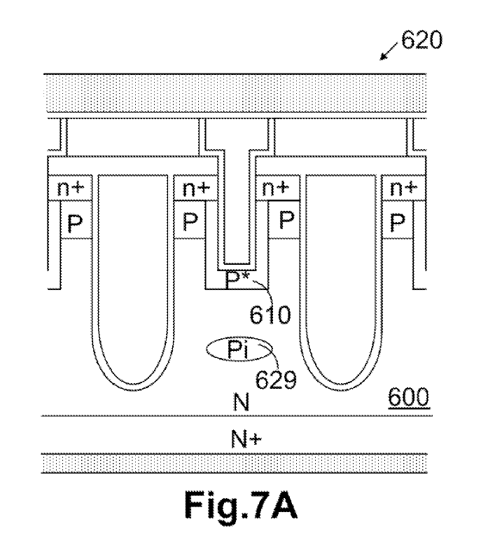

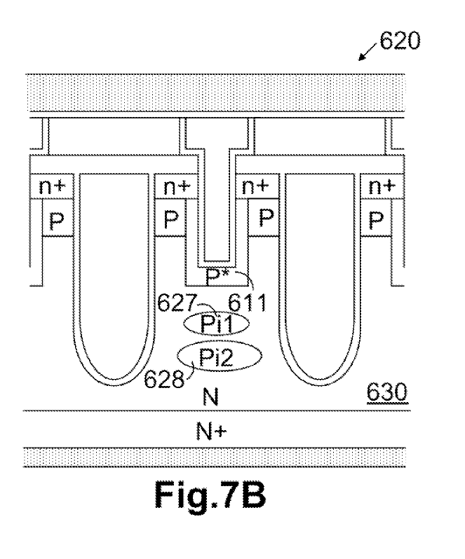

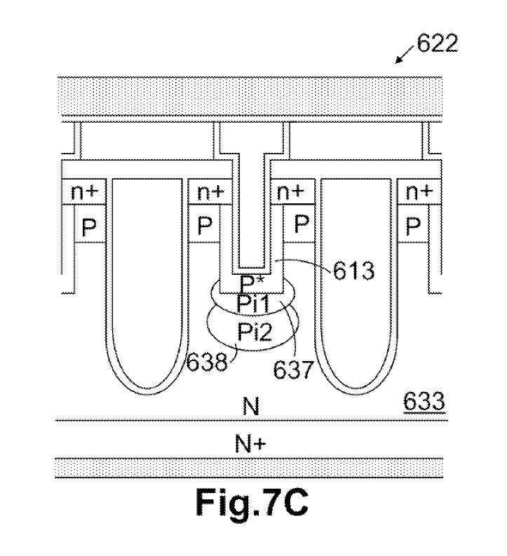

Please refer to FIG. 7A for another preferred N-channel trench MOSFET 620 with super pinch-off regions according to the present invention, which has similar configuration to FIG. 2 except that, there is an additional single implanted P type pinch-off island Pi 629 in N epitaxial layer 600 underneath anti-PT P* region 610 and between two adjacent trenched gates to form a third type pinch-off region between the trenched gate sidewall and the single implanted P type pinch-off island Pi 629 for further Idsx reduction.

Please refer to FIG. 7B for another preferred N-channel trench MOSFET 621 with super pinch-off regions according to the present invention, which has similar configuration to FIG. 2 except that, there are additional multiple implanted P type pinch-off islands Pi1 627 and Pi2 628 in N epitaxial layer 630 underneath anti-PT P* region 611 and between two adjacent trenched gates to further Idsx reduction.

Please refer to FIG. 7C for another preferred N-channel trench MOSFET 622 with super pinch-off regions according to the present invention, which has similar configuration to FIG. 2 except that, there is an additional P type pinch-off column formed by multiple implanted P type pinch-off islands Pi1 637 and Pi2 638 in N epitaxial layer 633 underneath anti-PT P* region 613 and between two adjacent trenched gates to further Idsx reduction. Comparing to FIG. 7B, the P type pinch-off island Pi1 637 in FIG. 7C is surrounding the bottom of the anti-PT P* region 613.

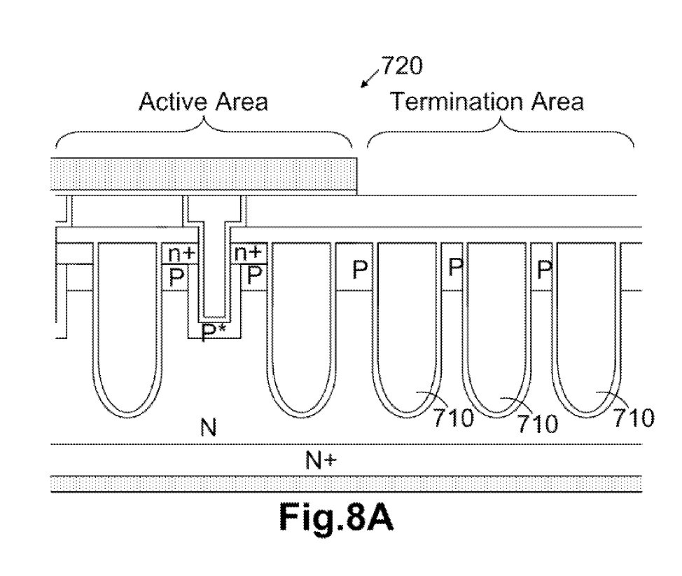

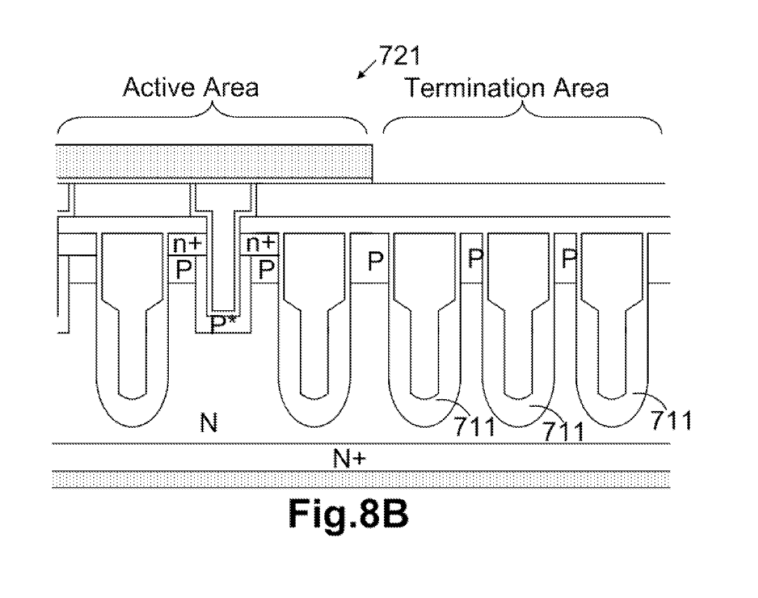

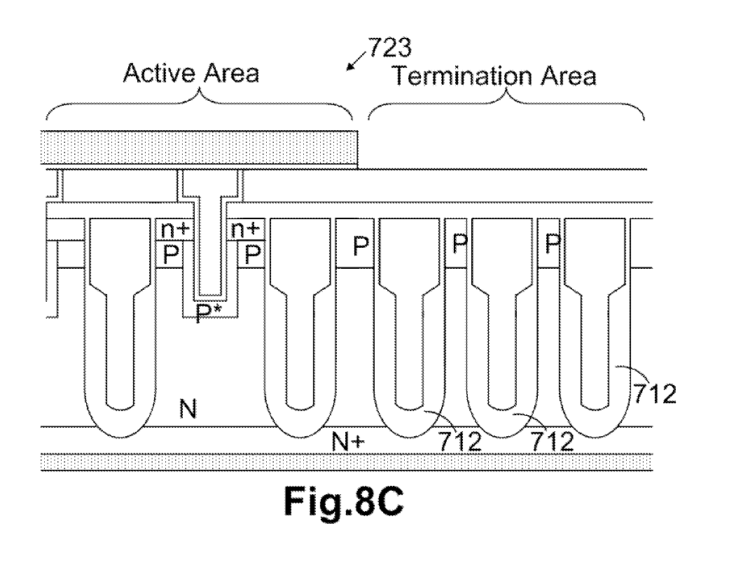

Please refer to FIG. 8A for another preferred N-channel trench MOSFET 720 with super pinch-off regions according to the present invention, which has similar configuration to FIG. 2 except that, the N-channel trench MOSFET 720 in FIG. 8A further comprises a termination area comprising multiple trenched gates 710 having floating voltage and same gate structure as trenched gates in active area, therefore shallow P body can be used without degrading BV. Moreover, P body mask can be saved for cost reduction.

Please refer to FIG. 8B for another preferred N-channel trench MOSFET 721 with super pinch-off regions according to the present invention, which has similar configuration to FIG. 5A except that, the N-channel trench MOSFET 721 in FIG. 8B further comprises a termination area comprising multiple trenched gates 711 having floating voltage and same gate structure as trenched gates in active area, therefore shallow P body can be used without degrading BV. Moreover, P body mask can be saved for cost reduction.

Please refer to FIG. 8C for another preferred N-channel trench MOSFET 723 with super pinch-off regions according to the present invention, which has similar configuration to FIG. 5B except that, the N-channel trench MOSFET 723 in FIG. 8C further comprises a termination area comprising multiple trenched gates 712 having floating voltage and same gate structure as trenched gates in active area, therefore shallow P body can be used without degrading BV. Moreover, P body mask can be saved for cost reduction.

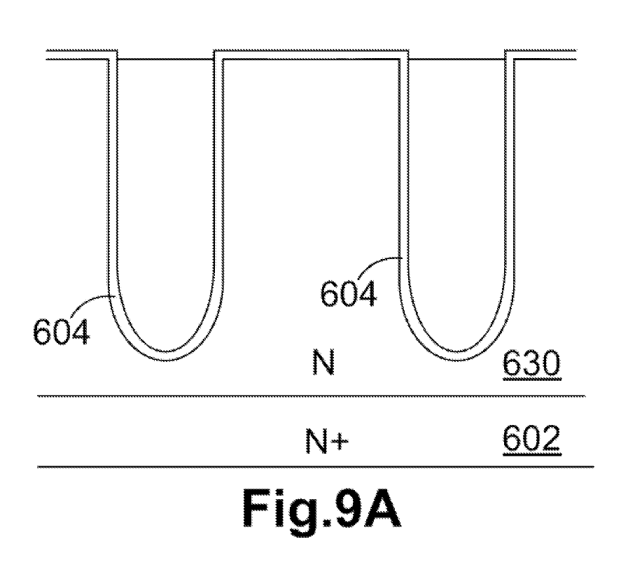

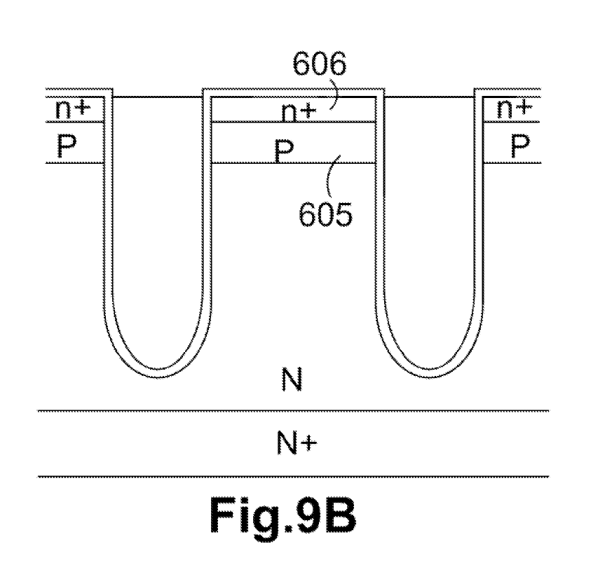

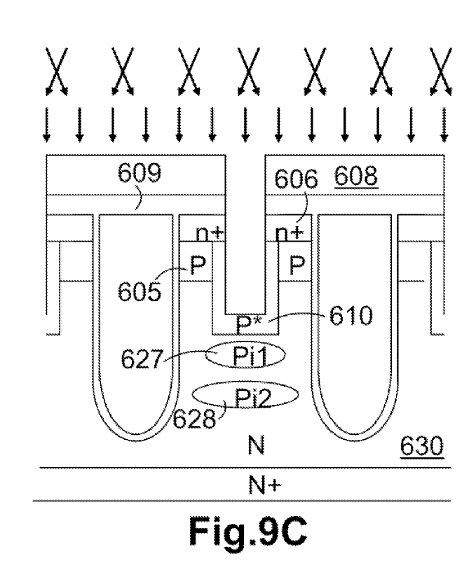

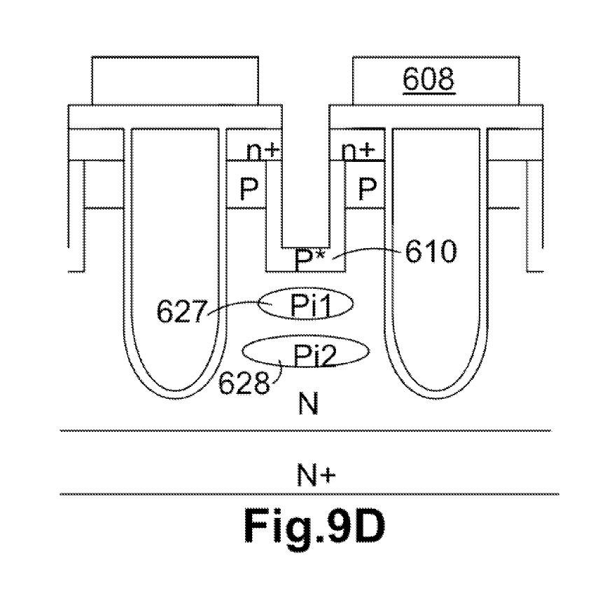

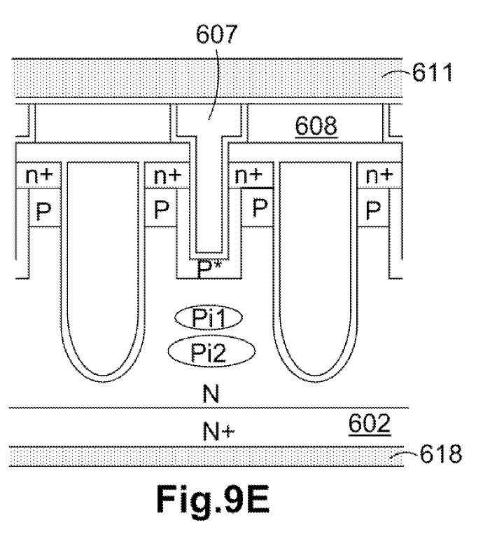

FIGS. 9A to 9E are a serial of exemplary steps that are performed to form the preferred N-channel trench MOSFET in FIG. 7B. In FIG. 9A, an N epitaxial layer 630 is grown on an N+ substrate 602. A trench mask (not shown) is applied to open a plurality of gate trenches by trench etching process in the N epitaxial layer 630. Then, a sacrificial oxide layer (not shown) is grown and etched off to remove damage along the sidewall and bottom surface of the gate trenches caused by the trench etching process. Next, an oxide layer is deposited or grown overlying the top surface of the N epitaxial layer 630 and the inner surface of the gate trenches to serve as gate oxide 604, onto which a doped poly-silicon 603 is deposited and then etched back by CMP (Chemical Mechanical Polishing) or plasma etching to keep the doped poly-silicon 603 within the gate trenches.

In FIG. 9B, over the entire top surface, a step of P type dopant Ion Implantation is carried out for the formation of P body regions 605, and then followed by an optional step of diffusion for P body drive-in. Then, after applying a source mask or not, a step of N type dopant Ion Implantation is carried out for the formation of n+ source regions 606, and then followed by an optional step of diffusion for n+ source drive-in.

In FIG. 9C, a layer of NSG 609 and a layer of BPSG 608 are successively deposited onto the top surface of the N epitaxial layer 630 and followed by a step of BPSG flow. Then, after applying a contact mask (not shown), contact trench is etched penetrating through the BPSG layer 608, the NSG layer 609, the n+ source region 606, the P body region 605 and extending into the N epitaxial layer 630 by successively dry oxide etching and dry silicon etching. Next, a step of BF2 Ion Implantation of zero degree and angle degree or only angle degree is carried out for formation of anti-PT P* region 610 surrounding the bottom and the sidewall of the contact trench below the n+ source region 605. After that, another Boron Ion Implantations of zero degree are carried out for formation of implanted P type pinch-off islands Pi1 627 and Pi2 628 in the N epitaxial layer 630 underneath the anti-PT P* region 610 between two adjacent trenched gates.

In FIG. 9D, a step of RTA (Rapid Thermal Annealing) is first carried out to activate dopant in the anti-PT P* region 610, in the P type pinch-off islands Pi1 627 and Pi2 628. Then, performing dilute HF dip to enlarge contact CD (Critical Dimension) in the BPSG layer 608.

In FIG. 9E, a barrier layer of Ti/TiN or Co/TiN or Ta/TiN is deposited along the inner surface of the contact trench and followed by a step of RTA to form silicide. Then, tungsten metal is deposited onto the barrier layer and then etched back to form tungsten plug 607 within the contact trench. Next, onto the BPSG layer 608 and the tungsten plug 607, a resistance-reduction layer of Ti or Ti/TiN and metal layer Al alloys or Ni/Ag are successively deposited and then patterned by a metal mask (not shown) to form source metal. Last, back metal of Ti/Ni/Ag is deposited on the rear side of the N+ substrate 602 to act as drain electrode after back grinding.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET with super pinch-off regions comprising:
a semiconductor chip comprising a substrate of a first conductivity doping type and an epitaxial layer of said first conductivity doping type, wherein said epitaxial layer formed onto top surface of said substrate and having lower doping concentration than said substrate;
a plurality of trenched gates extending from top surface of said semiconductor chip, said trenched gates filled with a conductive material insulated by a gate oxide layer from said semiconductor chip;
a source region of said first conductivity doping type located near top surface of a mesa which defined by an area between every two adjacent of said trenched gates;
a body region of a second conductivity doping type located in said mesa below said source region and adjacent to sidewall of said trenched gate;
a contact interlayer formed onto said top surface of said semiconductor chip;
a trenched source-body contact filled with a metal plug penetrating through said contact interlayer, said source region and said body region, and extending into said epitaxial layer in said mesa, wherein depth of said trenched source-body contact is shallower than bottom of said trenched gate;
an anti-punch through region of said second conductivity doping type wrapping around sidewall and bottom of said trenched source-body contact below a portion of said source region, wherein said anti-punch through region having higher doping concentration than said body region, and junction depth of said body region in said epitaxial layer is shallower than that of said anti-punch through region in a portion below bottom of said trenched source-body contact.

2. The trench MOSFET of claim 1, wherein said mesa width between every two adjacent of the trenched gates is less than 1.3 um.

3. The trench MOSFET of claim 1 further comprises a narrow mesa between sidewall of said anti-punch through region and adjacent said trenched gate having a mesa width less than 0.5 um.

4. The trench MOSFET of claim 1, wherein said source region has a doping concentration along a channel region same as that along said trenched source-body contact region at a same distance from top surface of said epitaxial layer, and junction depth of said source region along said channel region is same as along said trenched source-body contact.

5. The trench MOSFET of claim 1, wherein said source region has a doping concentration along a channel region lower than along said trenched source-body contact region at a same distance from top surface of said epitaxial layer, and junction depth of said source region along said channel region is shallower than that along said trenched source-body contact, and doping profile of said source region along said top surface of said epitaxial layer has a Gaussian-distribution from said trenched source-body contact to said channel region.

6. The trench MOSFET of claim 1, wherein said contact interlayer comprising a BPSG layer and an NSG layer beneath.

7. The trench MOSFET of claim 3, wherein said trenched source-body contact having greater trench width within said BPSG layer than within said NSG layer.

8. The trench MOSFET of claim 1, wherein said trenched source-body contact having vertical sidewall within said source region, said body region and said epitaxial layer.

9. The trench MOSFET of claim 1, wherein said trenched source-body contact having tapered sidewall within said source region, said body region and said epitaxial layer.

10. The trench MOSFET of claim 1, wherein said trenched source-body contact having vertical sidewall within said source region while having tapered sidewall within said body region and said epitaxial layer.

11. The trench MOSFET of claim 1, wherein said gate oxide is single gate oxide.

12. The trench MOSFET of claim 1, wherein said gate oxide is double gate oxide for Qgd reduction, each of said trenched gates includes an upper gate portion and a lower gate portion wherein said lower gate portion is surrounded with a lower gate oxide layer having a greater thickness than an upper gate oxide layer surrounding said upper gate portion, and said body region disposed above said lower gate portion of said trenched gate.

13. The trench MOSFET of claim 12, wherein the portion of said lower gate oxide layer having greater thickness is encompassed in said epitaxial layer and not reaching said substrate.

14. The trench MOSFET of claim 12, wherein the portion of said lower gate oxide layer having greater thickness penetrates into said substrate.

15. The trench MOSFET of claim 1, wherein said metal plug is tungsten plug padded by a barrier layer of Ti/TiN or Co/TiN or Ta/TiN.

16. The trench MOSFET of claim 1 further comprising a source metal padded by a resistance-reduction layer of Ti or Ti/TiN beneath which formed onto said contact interlayer and connecting to said metal plug.

17. The trench MOSFET of claim 1 further comprising a single implanted pinch-off island of said second conductivity doping type in said epitaxial layer underneath said anti-punch through region and between every two adjacent of said trenched gates.

18. The trench MOSFET of claim 1 further comprising multiple implanted pinch-off islands of said second conductivity doping type in said epitaxial layer underneath said anti-punch through region and between every two adjacent of said trenched gates.

19. The MOSFET of claim 1 further comprising an implanted pinch-off column region formed by multiple implanted pinch-off islands of said second conductivity doping type in said epitaxial layer underneath said anti-punch through region and between every two adjacent of said trenched gates.

20. The trench MOSFET of claim 1 further comprising a termination area comprising multiple floating trenched gates.

21. The trench MOSFET of claim 1, wherein said conductive material in said trenched gate is doped poly-silicon of said first conductivity doping type.

22. The trench MOSFET of claim 1, wherein said conductive material in said trenched gate is doped poly-silicon of said second conductivity doping type.

23. The trench MOSFET of claim 1, wherein said first conductivity doping type is N type, and said second conductivity type is P type.

24. The trench MOSFET of claim 1, wherein said first conductivity doping type is P type, and said second conductivity type is N type.

25. A method for manufacturing a trench MOSFET with super pinch-off regions comprising the steps of:
opening a plurality of gate trenches in an epitaxial layer of a first conductivity type which supported onto a substrate of said first conductivity type;
forming a gate oxide layer covering inner surface of said gate trenches and top surface of said epitaxial layer;
depositing doped poly-silicon layer onto said gate oxide layer and etching back to keep said doped poly-silicon within said gate trenches;
carrying out ion implantation of a second conductivity doping type dopant for formation of body region;
carrying out ion implantation of said first conductivity doping type dopant for formation of source region;
depositing a contact interlayer onto entire top surface;
applying a contact mask and carrying out dry oxide etching and dry silicon etching successively to open a contact trench between two adjacent of said gate trenches through said contact interlayer, said source region, said body region and into said epitaxial layer to form trenched source-body contact;
carrying out anti-punch through ion implantation of said second conductivity doping type dopant through said trenched source-body contact for formation of anti-punch through region surrounding bottom and sidewall of said contact trench below said source region.

26. The method of claim 25 further comprising a body diffusion step after body ion implantation.

27. The method of claim 25 further comprising applying a source mask before source ion implantation.

28. The method of claim 25 further comprising a source diffusion step after source ion implantation.

29. The method of claim 25 wherein said anti-punch through ion implantation is carried out with combination of zero degree ion implantation and angle ion implantation.

30. The method of claim 25 wherein said anti-punch through ion implantation is carried out with angle ion implantation.

31. The method of claim 25 further comprising additional zero degree ion implantation of said second conductivity doping type through said trenched source-body contact for formation of implanted pinch-off islands or column.

32. The method of claim 25 wherein said contact interlayer is combination of BPSG and NSG layers.

33. The method of claim 32 further comprising dilute HF dip step to enlarge contact CD of said contact trench in said BPSG layer.

34. The method of claim 25 further comprising the steps of:
carrying out RTA to activate dopant in said anti-PT region;
depositing a barrier layer of Ti/TiN or Co/TiN or Ta/TiN along inner surface of said trenched source-body contact and performing a step of RTA to form silicide;
depositing tungsten metal onto said barrier layer and etching back to form tungsten plug;
depositing a resistance reduction layer of Ti or Ti/TiN onto said BPSG layer and said tungsten plug;
depositing a front metal of Al alloys or Ni/Ag onto said resistance-reduction layer;
applying a metal mask to pattern said front metal and said resistance-reduction layer to form source metal;
grinding rear side of said substrate and depositing a back metal of Ti/Ni/Ag on rear side of said substrate to form drain electrode.
